(19) United States
(12) Patent Application Publication
(10) Pub. No.: US 2011/0190987 A1
(43) Pub. Date: Aug. 4, 2011

(54) OCCUPANT DETECTION SYSTEM AND METHOD

(75) Inventors: Kevin D. Kincaid, Kokomo, IN (US); Robert K. Constable, Kokomo, IN (US)

(73) Assignee: DELPHI TECHNOLOGIES, INC., Troy, MI (US)

(21) Appl. No.: 12/700,266

(22) Filed: Feb. 4, 2010

(51) Int. Cl. G06F 7/00; G01R 27/26; B60R 21/00

(52) U.S. Cl. 701/45; 324/681; 701/36

(57) ABSTRACT

An occupant detection system, a controller for an occupant detection system and a method of detecting an occupant. The presence or absence of the occupant varies the dielectric properties of an area proximate to influence the electrical impedance of the electrode. The electrode impedance is determined based on based on the excitation signal frequency, the excitation signal magnitude, and the electrode signal magnitude, and thereby determine an occupant presence based on the electrode impedance. The excitation signal magnitude is adjusted to optimize the electrode signal magnitude. The electrode signal magnitude is optimized to be large enough to be accurately measured, but not so large as to cause excessive radiated emissions. The excitation signal magnitude may be adjusted for each excitation signal frequency so the electrode signal magnitude is optimized regardless of frequency.

### TECHNICAL FIELD OF INVENTION

The invention generally relates to vehicle passenger occupant detection, and more particularly relates to a system and method for determining an occupant near an electrode in response to an excitation signal.

### BACKGROUND OF INVENTION

It is known to selectively enable or disable a vehicle air bag or other occupant protection device based on the presence of an occupant in a seat. It has been proposed to place electrically conductive material in a vehicle seat to serve as an electrode for detecting the presence of an occupant in the seat. For example, U.S. Patent Application Publication No. 2009/0267622 A1, which is hereby incorporated herein by reference, describes an occupant detector for a vehicle seat assembly that includes an occupant sensing circuit that measures an electrode impedance. The presence of an occupant affects the electrode impedance, predominately the capacitive part of the electrode impedance. Humidity and liquid moisture also affects the electrode impedance, predominately the resistive part of the electrode impedance

The electrode impedance may be measured by providing a reference impedance device such as a capacitor to form an alternating current voltage divider. Since the value of the reference impedance device is known, the value of the electrode impedance can be determined by applying a sinusoidal excitation signal at various frequencies to the voltage divider and comparing the electrode signal magnitude to the excitation signal magnitude. The electrode signal magnitude is generally limited to avoid violating certain radiated emissions standards. Typically the excitation signal magnitude is fixed at a value that will avoid excessive electrode signal magnitude for any of the excitation signal frequencies. However, as the capacitive part of the electrode impedance increases due to the presence of an occupant and the resistive part of the electrode impedance decreases due to increasing humidity or the presence of liquid moisture, the electrode signal magnitude decreases, thereby decreasing the accuracy of determining the electrode signal magnitude.

### SUMMARY OF THE INVENTION

In accordance with one aspect of this invention, an occupant detection system is provided. The occupant detection system includes an electrode, a reference impedance device and a controller. The electrode is arranged proximate to an expected location of an occupant for sensing an occupant presence proximate thereto. The electrode is configured to provide an electrode impedance indicative of the occupant presence. The reference impedance device has a first terminal and a second terminal. The first terminal is coupled to the electrode to form a voltage divider network. The controller is coupled to the second terminal and is configured to output an excitation signal on the second terminal to generate an electrode signal on the electrode. The excitation signal has an excitation signal frequency and an excitation signal magnitude. The electrode signal has an electrode signal magnitude. The controller is configured to determine said controller further configured to determine an occupant presence based on the excitation signal frequency, the excitation signal magnitude, and the electrode signal magnitude. The controller is further configured to adjust the excitation signal magnitude based on the electrode signal magnitude.

In another aspect of the present invention, a controller in an occupant detection system is provided. The occupant detection system has an electrode arranged proximate to an expected location of an occupant for sensing an occupant presence proximate thereto. The electrode is configured to provide an electrode impedance indicative of the occupant presence. The controller includes a reference impedance device, a signal generator, a voltage detector, and a processor. The reference impedance device has a first terminal and a second terminal. The first terminal is coupled to the electrode to form a voltage divider network. The signal generator is configured to output an excitation signal on the second terminal to generate an electrode signal on the electrode. The excitation signal has an excitation signal frequency and an excitation signal magnitude. The electrode signal has an electrode signal magnitude. The voltage detector is configured to determine the electrode signal magnitude. The processor is configured to determine the electrode impedance based on the excitation signal frequency, the excitation signal magnitude, and the electrode signal magnitude. The processor is also configured to determine an occupant presence based on the electrode impedance. The processor is further configured to adjust the excitation signal magnitude based on the electrode signal magnitude.

In yet another aspect of the present invention, a method for detecting a vehicle occupant is provided. An electrode is arranged to provide an electrode impedance indicative of an occupant presence proximate thereto. The electrode is coupled to a reference impedance device to form a voltage divider network. An excitation signal is output to the voltage divider network. The excitation signal has an excitation signal frequency and an excitation signal magnitude. An electrode signal is generated in response to the excitation signal. The electrode signal has an electrode signal magnitude. An occupant presence is determined based on the excitation signal frequency, the excitation signal magnitude, and the electrode signal magnitude. The excitation signal magnitude is adjusted based on the electrode signal magnitude.

Further features and advantages of the invention will appear more clearly on a reading of the following detail description of the preferred embodiment of the invention, which is given by way of non-limiting example only and with reference to the accompanying drawings.

### BRIEF DESCRIPTION OF DRAWINGS

The present invention will now be described, by way of example with reference to the accompanying drawings, in which:

FIG. 1 block diagram of an occupant detection system, according to one embodiment;

FIG. 2 is a perspective view of a seat assembly incorporating the occupant detection system shown in FIG. 1;

FIG. 3 is a block/circuit diagram illustrating one embodiment the occupant detection system shown in FIG. 1; and

FIG. 4 is a flow chart illustrating a method to determine an occupant residing in the seat assembly shown in FIG. 2.

### DETAILED DESCRIPTION OF INVENTION

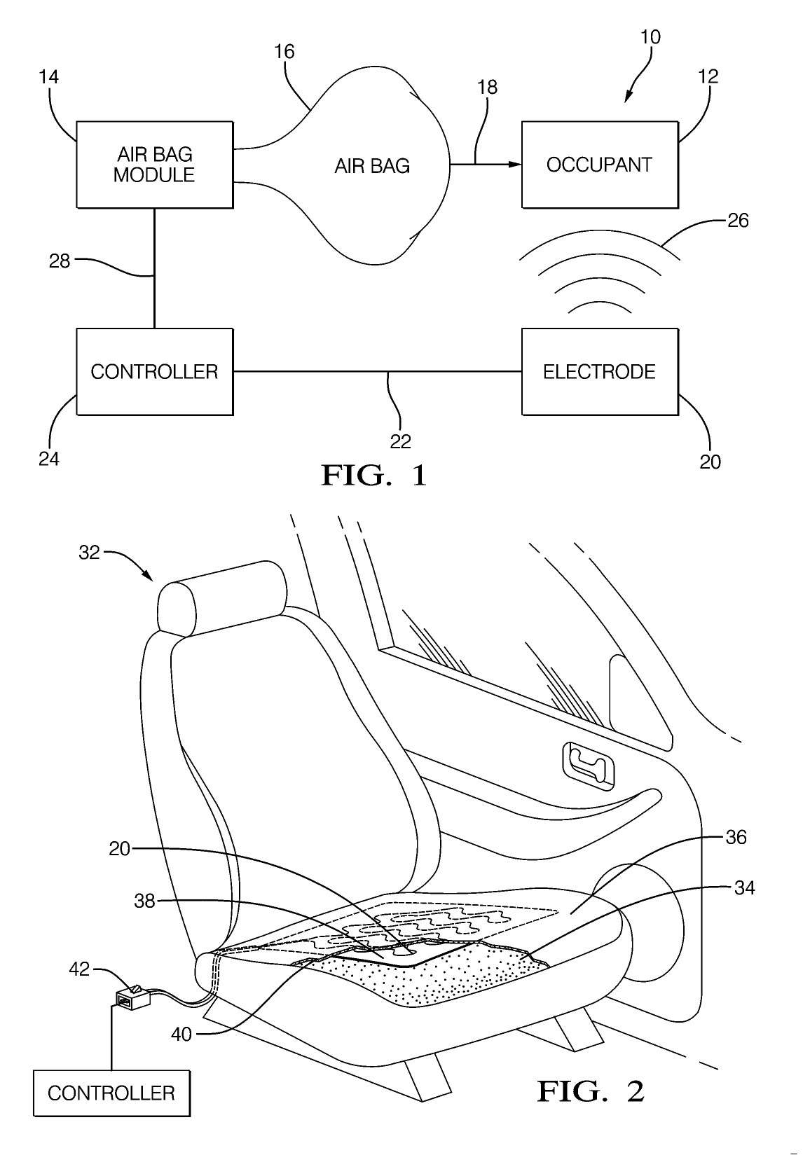

In accordance with an embodiment of an occupant detector, FIG. 1 illustrates an occupant detection system 10 for determining the presence an occupant 12 seated in a vehicle seat assembly 32 as seen in FIG. 2. The occupant may be an adult or an infant in a child seat. Determining an occupant presence in a vehicle seat may include characterizing the occupant (e.g., adult versus infant) for enabling or disabling an air bag module 14 or other passenger protection devices in the vehicle. The occupant detection system 10 may be used with an air bag module 14 that deploys an air bag 16 as indicated by an arrow 18 to restrain or protect the occupant 12 in the event of a vehicle collision. It is advantageous to disable the air bag module 14 if the vehicle seat is empty or occupied by an infant in a child seat so the air bag 16 is not unnecessarily deployed. As will be explained in more detail below, the occupant detection system 10 includes an electrode 20 that generates an electric field 26 in response to an electrode signal 22 output by a controller 24, thereby causing the electrode 20 to provide or exhibit an electrode impedance. In one embodiment, the controller 24 may use the electrode impedance provided by the electrode 20 to determine an occupant presence. Determining an occupant presence may be useful for determining an air bag activation signal 28 that arms or disarms the air bag module 14. The air bag module 14 may receive the activation signal 28 from the controller 24 to arm the air bag module 14 so that a signal from a collision detection system (not shown) can deploy the air bag 16. It should be appreciated that the occupant detection system 10 may be used for other vehicle functions such as activating a seat belt warning if the seat belt is not properly employed.

FIG. 2 illustrates an exemplary embodiment of the seat assembly 32 suitable for use by the occupant detection system 10 determine the presence of the occupant 12 (not shown in FIG. 2) on or near the seat assembly 32. The seat assembly 32 is illustrated in a vehicle passenger compartment, but could be used in any kind of vehicle, such as an airplane. The seat assembly 32 has a seat cushion 34 for providing a seating surface 36 to support the occupant 12. Seat cushion 34 is suitably made of foam having characteristics suitable for seating use. Adjacent the seating surface 36 is an embodiment of the electrode 20 in the form of a wire coupled to a mat 38 that simplifies arranging the electrode 20 in seat assembly 32. The electrode 20 can be made of a variety of electrically conductive materials suitable for use adjacent the seating surface 36. Exemplary materials for forming the electrode 20 include metal wire, conductive fiber, conductive ink, metal foil, and metal ribbon. The cushion 34 is covered with covering 40 to protect the cushion 34 and the electrode 20, and to make the appearance of seat assembly 30 attractive.

The electrode 20 radiates an electric field 26 in response to the electrode signal 22 and thereby provides an electrode impedance. The value of the electrode impedance in this embodiment is dependent, at least in part, on the coupling of the electric field 26 from the electrode 20 to the vehicle and is affected by the presence or absence of an occupant 12 residing in the seat assembly 32. The electrode 20 may be arranged to be located adjacent or proximate to the seating surface 36. Such an arrangement improves occupant detection sensitivity and accuracy for detecting an occupant near seating surface 36 by maximizing the coupling of electrical field 26 to the occupant 12. As such, the electrode impedance is indicative of the occupant presence. The electrode 20 may be coupled to the controller 24 by a connector 42 so electrode 20 can be readily connected to the controller 24.

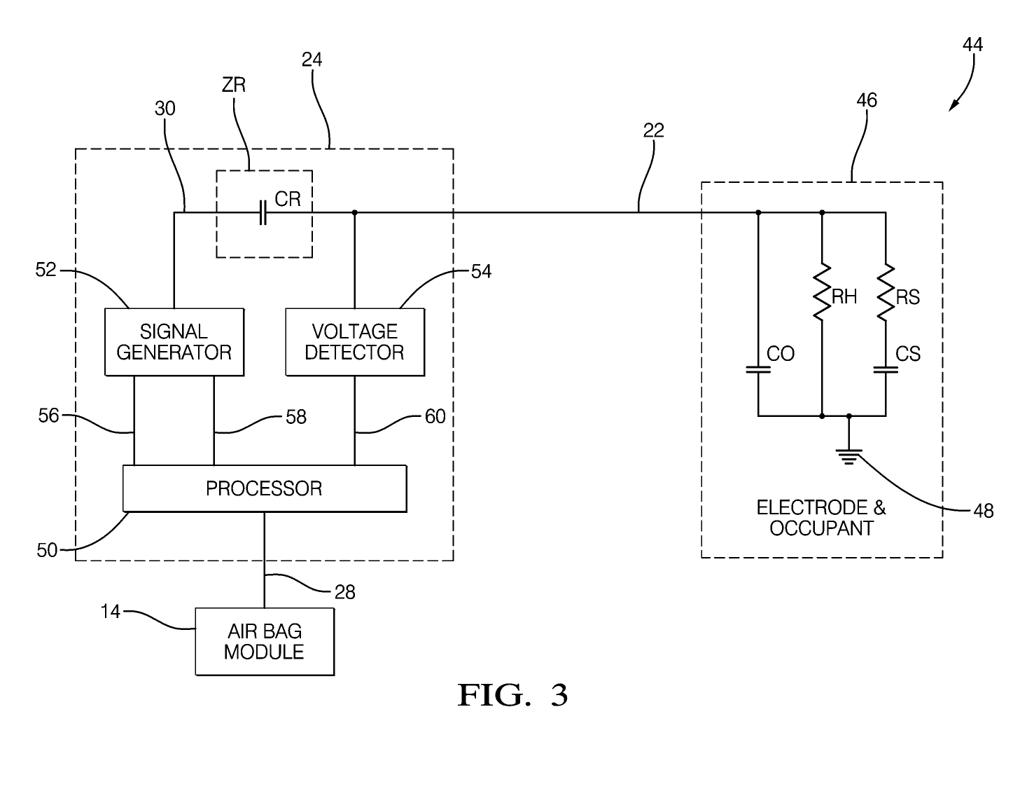

FIG. 3 illustrates an exemplary embodiment of a circuit diagram 44 for describing the operation of the occupant detection system 10. While not subscribing to any particular theory, it has been observed that variation in the electrode impedance may be indicative of the presence of occupant 12 and other environmental factors. The circuit diagram 44 includes an electrode/occupant model 46 illustrating various electrical components that correspond to phenomena that may influence the electrode impedance provided by the electrode 20. For example, capacitor CO may be characterized as two spaced apart plates with material having a dielectric constant occupying the space between the capacitor CO plates. The dielectric constant of the material influences the capacitance value of the capacitor CO. In the model 46, the electrode 20 may be characterized as corresponding to the plate of capacitor CO connected to network signal 22. The other plate of capacitor CO then corresponds to the frame and body of the vehicle surrounding the occupant 12 and is shown as being connected to a reference ground 48. It follows that the dielectric material between the capacitor CO plates corresponds at least in part to the occupant 12.

It has been observed that a capacitor portion of the electrode impedance corresponding to a capacitance value of capacitor CO when the seat is empty is lower than the capacitance value of capacitor CO when the seat is occupied. The presence of a large adult versus a small child, or the absence of an occupant may vary the dielectric constant of the dielectric material between the plates and thereby varies the capacitance value of capacitor CO. A typical capacitance value for an empty seat assembly 32 in an automobile is about 50 pF to about 100 pF. When an adult occupies the seat assembly 32, the capacitive term typically increases about 30 pF to about 80 pF. As such, the electrode 20 has an electrode impedance that is indicative of occupant presence and occupant size.

The model 46 also illustrates a resistor RH in parallel with capacitor CO that suggests a resistive path for direct current that corresponds with dielectric leakage of a capacitor. The value of resistor RH may be dependent on the materials used to make cushion 34 and seat cover 40, and on other environmental conditions such as relative humidity, temperature, or changes due to wear and breakdown of the materials used to form the seat assembly 32. It has been observed that the resistance value of resistor RH decreases as the humidity in and around the seat assembly 32 increases, or if liquid moisture is present in or on the seat assembly 32. A typical resistance value of resistor RH for a dry seat assembly 32 corresponding to a resistive portion of the electrode impedance is greater than 1.0MΩ (1 million Ohms). If the humidity level is high, the resistor RH may be below 1.0 MΩ. If the seat is wet due to a spilled drink for example, the resistor RH may be below about 0.1 MΩ.

FIG. 3 further illustrates an embodiment of controller 24. In this embodiment, the controller 24 has a reference impedance device ZR that includes a first terminal connected to the electrode signal 22 and so form a voltage divider network with the electrode impedance of the model 46. The voltage divider network formed by reference impedance device ZR having a known reference impedance value may be used to determine the electrode impedance value of the electrode 20. The controller 24 includes a signal generator 52 configured to output an excitation signal 30 on the second terminal of reference impedance device ZR. The signal generator 52 in this embodiment receives a frequency control signal 56 and a magnitude control sign 58 from a processor 50 to generate the excitation signal 30 characterized as having an excitation signal frequency and an excitation signal magnitude. The excitation signal 30 coupled through reference impedance device ZR causes the electrode signal 22 to be generated. The electrode signal 22 may also be characterized as having an electrode signal frequency and an electrode signal magnitude.

In this embodiment of controller 24, a voltage detector 54 is coupled to the first terminal of reference impedance device ZR and electrode model 46 and may be configured to determine an electrode signal magnitude and send a magnitude signal 60 to processor 50. The processor 50 in this embodiment is configured to determine the electrode impedance based on the excitation signal frequency, the excitation signal magnitude, and the electrode signal magnitude. The processor 50 may be further configured to determine an occupant presence based on the electrode impedance. The signal generator 52 and the voltage detector 54 are shown as being separate from the processor 50. However, it should be understood that other control circuitry or devices that incorporate the functions of the processor 50, the signal generator 52 and the voltage detector 54 into a single device or alternative devices may be employed

As the capacitance value of capacitor CO increases due to the presence of an occupant, or the resistance value of resistor RH decreases due to the presence of humidity or liquid moisture, the electrode signal magnitude decreases if the excitation signal magnitude is fixed. As the magnitude of electrode signal 22 decreases, it may become difficult for the voltage detector 54 to determine electrode signal magnitude with sufficient accuracy to determine the presence of an occupant 12. The processor 50 may also be configured to adjust the excitation signal magnitude based on the electrode signal magnitude. Alternately, the adjustment of electrode signal magnitude may be by way of an arrangement of operational amplifiers and passive components configured to monitor the electrode signal magnitude and adjust the excitation signal magnitude accordingly.

Being able to control the electrode signal magnitude is advantageous in that the voltage detector 54 receives an electrode signal 22 having adequate magnitude for an accurate determination. However, the electrode signal magnitude is limited to avoid creating excessive radiated emissions. By way of an example, it has been observed that excessive radiated emissions are not generated if the electrode signal magnitude is less than 0.070 Volts root-mean-squared (RMS). If the electrode signal magnitude is greater than 0.070 Volts RMS, then the signal has sufficient magnitude to be readily measured by commercially available equivalents of voltage detector 54.

In one embodiment, impedance ZM is provided by a capacitor CM. A suitable value for CM is 100 pF, according to one example. If capacitor CM is too large or too small, the voltage divider ratio of the electrode impedance ZM and the electrode impedance will be such that a suitable electrode signal magnitude can not be generated. Capacitors around 100 pF having electrical characteristics that are stable over time and temperature are readily available and economical.

Excitation signal frequencies in the range of 1.0 kHz to 1000 kHz may be employed, according to one embodiment. At the lower end of the range of frequencies a decreasing value of resistor RH may lead to low excitation signal magnitudes. At the higher end of the range of frequencies an increasing value of capacitor CO may also lead to low excitation signal magnitudes. As such, it is advantageous for the excitation signal magnitude to be adjusted independently of the excitation signal frequency. The processor 50 may also be configured to adjust the excitation signal magnitude such that the electrode signal magnitude is constant for any excitation signal frequency. In one embodiment, the excitation signal may suitably be a sinusoidal waveform. Determining the electrode impedance is simplified when a sinusoidal waveform is used, particularly when excitation signals at multiple frequencies are used to separately determine capacitance and resistance portions of the electrode impedance corresponding to capacitor CO and resistor RH in the electrode and occupant model 46. If the model 46 is more complicated than having only capacitor CO and resistor RH, such as including dielectric storage resistor RS and dielectric storage capacitor CS as illustrated in FIG. 3, then determining the various component values may require using an excitation signal at a plurality of frequencies. If model 46 were to include non-linear components having electrical characteristics that were dependent on an applied voltage for example, then determining the electrode impedance may require that the controller be configured to determine the electrode impedance based on a plurality of electrode signal magnitudes at the plurality of frequencies.

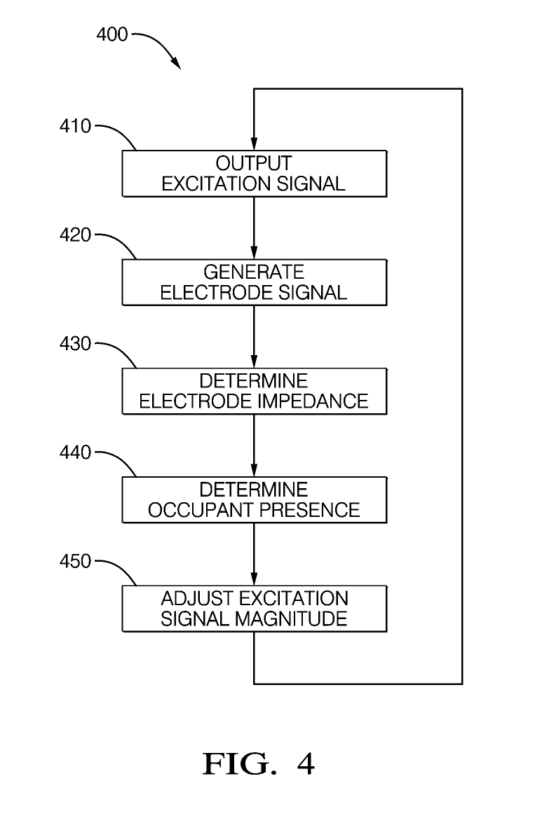

FIG. 4 illustrates an embodiment of a method 400 for detecting a vehicle occupant having an electrode 12 arranged to provide an electrode impedance indicative of an occupant presence proximate to the electrode 12. In one embodiment described above, the electrode 12 is coupled to a controller 24 that includes a reference impedance device ZR coupled to the electrode 20 to form a voltage divider network. At step 410, a signal generator 52 outputs an excitation signal 30 to the voltage divider network. The excitation signal 30 has an excitation signal frequency based on a frequency control signal 56 and an excitation signal magnitude based on a magnitude control signal 58 received by the signal generator 52 from a processor 50. At step 420 an electrode signal 22 is generated in response to the excitation signal 30. The electrode signal has an electrode signal magnitude. A voltage detector 54 determines the electrode signal magnitude and provides a magnitude signal 60 to the processor 50. At step 430, the processor 50 determines the electrode impedance based on the excitation signal frequency, the excitation signal magnitude, and the electrode signal magnitude. At step 440, the processor 50 determines an occupant presence based on the electrode impedance. At step 450, the processor adjusts the excitation signal magnitude based on the electrode signal magnitude to provide an electrode signal magnitude that is readily measured by the voltage detector. Appropriately adjusting the excitation signal magnitude assures that the electrode signal magnitude is large enough for the voltage detector 54 to readily measure the electrode signal magnitude with a suitable degree of accuracy, but not too large so as to cause excessive radiated emissions.

In another embodiment, a method may include adjusting the excitation signal magnitude such that the electrode signal magnitude is independent of the excitation signal frequency. Such an adjustment may be achieved such that the electrode signal magnitude is constant for any excitation signal frequency.

In another embodiment, a method may include the excitation signal being different sinusoidal waveforms. In this embodiment, the step of outputting an excitation signal may include outputting an excitation signal at a plurality of excitation frequencies. Such a method may include the step of determining the electrode impedance based on a plurality of electrode signal magnitudes at the plurality excitation frequencies. In another embodiment, a method may include the step of determining the activation status of an air bag module based on detecting the vehicle occupant.

Accordingly, an occupant detection system, a controller for an occupant detection system and a method of detecting an occupant is provided. The presence or absence of the occupant varies the dielectric properties of an area proximate to an electrode generating an electric field, and thereby influences the electrical impedance of the electrode. By determining the electrode impedance the presence of an occupant may be determined. The electric field is generated in response to an electrode signal arising from an excitation signal. The magnitude of the electrode signal is controlled by varying the magnitude of the excitation signal. By controlling the electrode signal magnitude, the electrode signal magnitude can be optimized to be large enough to be accurately determined using commonly available electronic devices, but not so large as to cause excessive radiated emissions that could interfere with the operation of other electrical devices. To determine the electrode impedance, the excitation signal may be output at more than one frequency, so the excitation signal magnitude may be adjusted for each frequency such that the electrode signal magnitude is optimized for each frequency. The system and method advantageously provide for enhanced signal-to-noise (s/n) ratio and improved measurement resolution that in turn improves the ability to differentiate between these loads and correctly classify the occupant. This is in contrast to other techniques that could be used to improve the magnitude of the signal at the input to the detector such as a gain stage that would amplify system noise as well as the desired signal.

While this invention has been described in terms of the preferred embodiments thereof, it is not intended to be so limited, but rather only to the extent set forth in the claims that follow.

We claim:

1. An occupant detection system comprising:
an electrode arranged proximate to an expected location of an occupant for sensing an occupant presence proximate thereto, said electrode configured to provide an electrode impedance indicative of the occupant presence;
a reference impedance device comprising a first terminal and a second terminal, said first terminal coupled to the electrode to form a voltage divider network; and
a controller configured to output an excitation signal on the second terminal to generate an electrode signal on the electrode, said excitation signal having an excitation signal frequency and an excitation signal magnitude, said electrode signal having an electrode signal magnitude, said controller further configured to determine an occupant presence based on the excitation signal frequency, the excitation signal magnitude, and the electrode signal magnitude, wherein said controller is further configured to adjust the excitation signal magnitude based on the electrode signal magnitude.

2. The occupant detection system in accordance with claim 1, wherein the excitation signal magnitude is adjusted such that the electrode signal magnitude is independent of the excitation signal frequency.

3. The occupant detection system in accordance with claim 1, wherein the excitation signal magnitude is adjusted such that the electrode signal magnitude is constant for any excitation signal frequency.

4. The occupant detection system in accordance with claim 1, wherein said controller is further configured to determine the electrode impedance based on the excitation signal frequency, the excitation signal magnitude, and the electrode signal magnitude, and determine an occupant presence based on the electrode impedance.

5. The occupant detection system in accordance with claim 1, wherein the electrode is adjacent a seating surface of a vehicle seat to sense the occupant seated in the vehicle seat.

6. The occupant detection system in accordance with claim 1, wherein the reference impedance device is a capacitor.

7. The occupant detection system in accordance with claim 1, wherein the excitation signal is a sinusoidal waveform.

8. The occupant detection system in accordance with claim 7, wherein the excitation signal comprises a plurality of frequencies.

9. The occupant detection system in accordance with claim 8, wherein the controller is configured to determine the electrode impedance based on a plurality of electrode signal magnitudes at the plurality of frequencies.

10. The occupant detection system in accordance with claim 1, said system further comprising an air bag module receiving an activation signal from the controller, wherein said activation signal is based on the occupant presence.

11. A controller in an occupant detection system comprising an electrode arranged proximate to an expected location of an occupant for sensing an occupant presence proximate thereto, said electrode configured to provide an electrode impedance indicative of the occupant presence, said controller comprising:
a reference impedance device comprising a first terminal and a second terminal, said first terminal coupled to the electrode to form a voltage divider network;
a signal generator configured to output an excitation signal on the second terminal to generate an electrode signal on the electrode, said excitation signal having an excitation signal frequency and an excitation signal magnitude, said electrode signal having an electrode signal magnitude;
a voltage detector configured to determine the electrode signal magnitude; and
a processor configured to determine the electrode impedance based on the excitation signal frequency, the excitation signal magnitude, and the electrode signal magnitude, and determine an occupant presence based on the electrode impedance, wherein said processor is further configured to adjust the excitation signal magnitude based on the electrode signal magnitude.

12. The controller in accordance with claim 10, wherein said processor is further configured to output an activation signal for activating an air bag module, wherein said activation signal is based on the occupant presence.

13. A method for detecting a vehicle occupant comprising the steps of:
arranging an electrode to provide an electrode impedance indicative of an occupant presence proximate thereto;
coupling the electrode to a reference impedance device to form a voltage divider network;
outputting an excitation signal to the voltage divider network, wherein said excitation signal has an excitation signal frequency and an excitation signal magnitude;
generating an electrode signal in response to the excitation signal, wherein said electrode signal has an electrode signal magnitude;
determining an occupant presence based on the excitation signal frequency, the excitation signal magnitude, and the electrode signal magnitude; and
adjusting the excitation signal magnitude based on the electrode signal magnitude.

14. The method in accordance with claim 13, wherein the excitation signal magnitude is adjusted such that the electrode signal magnitude is independent of the excitation signal frequency.

15. The method in accordance with claim 13, wherein the excitation signal magnitude is adjusted such that the electrode signal magnitude is constant for any excitation signal frequency.

16. The method in accordance with claim 13, wherein the step of determining the occupant presence is based on determining the electrode impedance, and determining the electrode impedance is based on the excitation signal frequency, the excitation signal magnitude, and the electrode signal magnitude.

17. The method in accordance with claim 13, wherein the excitation signal is a sinusoidal waveform and the step of outputting an excitation signal includes outputting an excitation signal at a plurality of excitation frequencies.

18. The method in accordance with claim 17, wherein the step of determining the electrode impedance is based on a plurality of electrode signal magnitudes at the plurality excitation frequencies.

19. The method in accordance with claim 13, further comprising the step of activating an air bag module based on determining an occupant presence.
